(19) United States
(12) Patent Application Publication
(10) Pub. No.: US 2023/0079069 A1
(43) Pub. Date: Mar. 16, 2023

(54) ELECTRONIC DEVICE

(71) Applicant: UCL BUSINESS LTD, London (GB)

(72) Inventors: Richard Jackman, London (GB); Alexander Pakpour-Tabrizi, London (GB)

(21) Appl. No.: 17/904,914

(22) PCT Filed: Feb. 23, 2021
(86) PCT No.: PCT/GB2021/050444

§ 371 Date: Aug. 24, 2022

(30) Foreign Application Priority Data
Feb. 24, 2020 (GB) 2002558.1

(51) Int. Cl. H01L 29/417; H01L 29/16; H01L 29/45; H01L 29/76; H01L 29/872; H01L 21/04; H01L 29/66

(52) U.S. Cl. CPC H01L 29/417; H01L 29/1602; H01L 29/45; H01L 29/7606; H01L 29/872; H01L 21/043; H01L 29/6603

(57) ABSTRACT

An electronic device, and method of producing an electronic device, are disclosed. The electronic device comprises a diamond substrate 10. Within the substrate 10 is an electrode 12, known as a ‘buried electrode’. A first surface 14 of the substrate 10 is provided with a conductive contact region 16. The electrode 12 is electrically connected to the contact region 16 by a conductive pillar 18. The electrode, conductive pillar, and contact region comprise modified portions of the diamond substrate, for example comprising at least one of graphitic carbon, amorphous carbon, and a combination of SP2 and SP3 phases of carbon, formed from a portion of diamond substrate.

### FIELD OF THE INVENTION

The present invention relates to a diamond-based electronic device.

### BACKGROUND OF THE INVENTION

It has long been desired to make electronic devices based on diamond because of the exceptional material properties of diamond. The majority of conventional device structures are of a ‘lateral’ design, with the electrodes on the same surface of the device (co-planar). This has problems, particularly for power applications, because the positioning of the electrode contacts, being adjacent to each other, places a limit on the maximum voltage capability, and the relatively shallow conductive channel (drift region) limits the current capacity.

Other devices of a ‘vertical’ design have been proposed, with contact electrodes on opposite sides of the diamond semiconductor, in a ‘sandwich’ configuration. However, there have been a number of problems. Conventional semiconductor processing techniques for silicon, such as lithography and etching, are very difficult and slow with diamond, and produce a low yield of devices. Furthermore, for semiconductor devices, the diamond is doped (typically with boron). To form good contacts, high doping (known as p++) is desired; but for a good high-voltage blocking performance, low doping (known as p−) is desired for the channel. Therefore it is necessary to modulate the doping of different regions during growth of the synthetic diamond. However, boron is a notorious contaminant of equipment used for diamond growth (such as by CVD), so it is difficult to produce lightly doped diamond adjacent to highly doped diamond; this means that the process is inefficient, slow, expensive, has a low yield, and low device reproducibility.

Another problem is that it is difficult to form back-gates or field plates with diamond.

### SUMMARY OF THE INVENTION

The present invention has been devised in view of the above problems.

Accordingly, one aspect of the present invention provides an electronic device comprising:
a diamond substrate;
an electrode provided within the substrate;
wherein the electrode comprises a 2D or 3D region of modified diamond substrate.

Another aspect of the invention provides a method of producing an electronic device according to the preceding aspect, the method comprising:
positioning a diamond substrate in a laser system;
exposing the substrate to laser radiation to modify the substrate to create the 2D or 3D electrode.

### DESCRIPTION OF THE DRAWINGS

Embodiments of the invention will now be described, by way of example only, with reference to the accompanying drawings, in which:

FIG. 1 is a schematic cross-section of an electronic device according to an embodiment of the invention which is a Schottky diode;

FIGS. 2 and 3 are schematic cross-sections of variants of the device of FIG. 1 according to further embodiments of the invention;

FIGS. 4, 5 and 6 are schematic cross-sections of structures comprising multiple electronic devices embodying the invention formed on a single substrate;

FIG. 7 is a schematic cross-section of an electronic device according to another embodiment of the invention which is a transistor;

FIG. 8 illustrates schematically an apparatus for producing an electronic device according to one embodiment of the invention;

FIGS. 9 and 10 are cross-sections of devices during stages of fabrication thereof; and

FIGS. 11 to 23 are schematic illustrations of electronic devices according to further embodiments of the invention.

In the drawings, like parts are given like reference signs, and duplicate description thereof is omitted.

### DETAILED DESCRIPTION OF THE INVENTION

Embodiments of the invention will firstly be described with reference to a Schottky diode being the electronic device, but this is merely an exemplary device; the invention is not limited only to being a Schottky diode. The features of these embodiments can be used, separately or in combination, in other electronic devices embodying the invention.

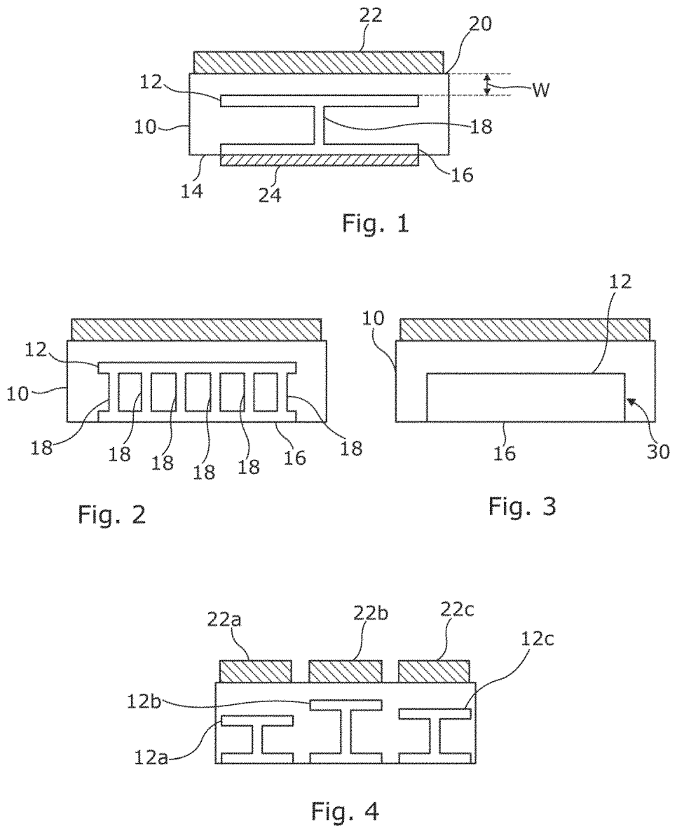

FIG. 1 shows a Schottky diode in cross-section as an electronic device according to an embodiment of the invention. The device comprises a diamond substrate 10. Within the substrate 10 is an electrode 12, which may also be known as a ‘buried electrode’. A first surface 14 of the substrate 10 is provided with a conductive contact region 16. The electrode 12 is electrically connected to the contact region 16 by a conductive pillar 18.

The substrate 10 is typically synthetic diamond, for example formed by CVD (chemical vapor deposition, including plasma-enhanced CVD) or by HPHT (high-pressure, high-temperature growth), which techniques are well-known in the art, or by a combination of methods such as CVD on top of an HPHT-formed diamond. In principle, naturally occurring diamond could also be used. Regardless of the underlying material and its method of fabrication, it can optionally be capped with a high quality, CVD-grown, diamond layer on top, also called a buffer layer, having a controlled impurity (dopant) level (such as boron or nitrogen).

The diamond substrate 10 of this embodiment is semi-conductive, preferably p-type, which can be achieved by doping with, for example, boron during formation/growth. The preferred dopant concentration is at least 10¹⁴ cm⁻³. If the dopant concentration is too high, such as greater than 10²¹ cm⁻³, then the diamond becomes metallic in terms of conductivity, and so reverse current blocking of a diode is poor. So ideally the dopant concentration is less than 10¹⁸ cm⁻³, such as 10¹⁷ cm⁻³. This may also be referred to as lightly doped (or ‘p-’ in the case of p-type doping).

In other devices embodying the invention, the diamond can be n-type, doped with, for example, nitrogen or phosphorous. The doping levels can be similar to those for p-type explained above.

The doping can be homogeneous, and it is not required to purposefully modulate the dopant concentration via any processing steps, though this possibility is not excluded.

The diamond substrate 10 can be a single crystal or can be poly-crystalline. One example of poly-crystalline diamond is ultrananocrystalline diamond (UNCD), typically grown as a relatively thin film on a support surface.

In the embodiment of FIG. 1, the diamond substrate 10 is in generally laminar form, such as a chip or wafer, with thickness up to 1 mm, and typically approximately 0.5 mm thick. The area of the substrate 10 is typically in the range of from 1 mm×1 mm up to 10 mm×10 mm, such as 2.5 mm×2.5 mm or 4 mm×4 mm, but can be outside of this range. The substrate is not limited to being square, but can be rectangular or other shapes, such as circular.

In this embodiment and in other embodiments of the invention, the electrode 12, contact region 16, and conductive pillar 18, are all formed of modified substrate. Regions of the diamond substrate are modified by exposure to electromagnetic radiation, such as from a laser. More details of a method according to the invention for producing the modified regions of the substrate will be described later. At sufficiently high electromagnetic radiation energy density, the diamond crystal structure is locally disrupted (modified) to some extent from the sp3 phase (diamond) to the sp2 phase (graphitic). The modified regions can take the form of amorphous carbon, comprising carbon bonded locally with a combination of sp3 and sp2 hybridized bonding. The total amount of modified material within these regions may in fact be as low as approximately 4%, so the structural integrity of the surrounding diamond lattice is maintained. The locally disrupted graphitic portions (or platelets) are not necessarily contiguous, but are sufficiently close as to allow ‘percolation’ electrical conduction throughout the region of modified substrate. For convenience, these regions of modified diamond substrate will be referred to herein as ‘graphitic’, but it is understood in this context that this term does not imply pure graphite sp2 bonding phase, and can encompass amorphous carbon, as well as diamond in which a relatively small proportion of the bonding has been modified, potentially in local pockets, but which enables electrical conduction through the modified region.

As shown in FIG. 1, the electrode 12 is spaced apart from the second surface 20 of the substrate 10 by a distance W, which distance is also known as the ‘channel width’ of the device. In this embodiment, a metal contact 22 in the form of a layer is provided on the second surface 20 to form a Schottky contact with the diamond substrate 10 to provide the diode property. When forward biased, there is a conductive path or ‘channel’ between the metal contact 22 and the electrode 12 though the intervening diamond substrate. Examples of metals for the Schottky contact include Al, Mo, Pt, Cr, W. A further layer of metal, such as Au, may optionally be formed on top of the contact 22 for good conductivity and to assist bonding to an external circuit.

The channel width W is typically in the range of from 1 to 50 μm, such as from 5 to 20 μm, for example approximately 10 to 11 μm. The formation of the electrode 12 within the substrate 10 enables such a small channel width to be achieved. If contacts were simply formed on the top and bottom surfaces of a diamond substrate 0.5 mm thick, then the series resistance through the diamond between the two contacts would be unacceptably high.

The thickness of the electrode 12 can typically be a few hundred nanometers, for example approximately 400 nm. The electrode 12 in this embodiment is in the form of a 2D plate or sheet (shown edge-on in FIG. 1) because its areal extent is much greater than its thickness. The area of the electrode 12 is substantially the same as that of the substrate 10, such as several square mm, (though a small gap can be left around the perimeter for structural reasons).

The electrode 12 does not have to be in the form of a continuous 2D plate (where an entire area has been modified to graphitic form without any gaps); an alternative form is a grid of wires. The fabrication time can be reduced because the wires can be laser-written to crisscross, or even as a series of parallel wires, but with some spacing between so that the every point does not have to be exposed. The electric field at a distance from the electrode greater than the wire spacing will be substantially the same as for a continuous 2D plate.

The contact region 16 of the device is to provide external ohmic contact to the electrode 12 of the Schottky diode via the conductive pillar 18. The contact region 16 comprises graphitic modified portion of the first surface 14 of the diamond substrate 10. The surface of the contact region 16 can be provided with a further metallization layer 24, for example comprising Ti Pt Au, or Cr Au. However, this metallization layer 24 is optional, and for simplicity it has been omitted from the illustrations of the further embodiments, although it could equally be provided.

FIG. 2 illustrates another embodiment of the invention, essentially the same as FIG. 1, but in which multiple conductive pillars 18 are provided between the electrode 12 and the back contact region 16. The conductive pillars 18 are distributed in a regular or irregular 2D array. The number, diameter, and distribution of the pillars 18 can be chosen to suit the current carrying requirements of the device. Other embodiments may be illustrated with a single pillar for convenience, but can be provided with multiple pillars, and vice versa.

FIG. 3 shows a further variant of the embodiments of FIGS. 1 & 2 in which the electrode 12, pillars 18, and contact region 16 are combined into a unified 3D modified region 30 of the substrate 10. Essentially this takes the case of multiple pillars to the extreme in which the pillars are contiguous in one larger block or single pillar. The 3D region of modified substrate of course does not have to be created from multiple pillars, but can be written or exposed in other ways, such as layer by layer, line by line, or pixel by pixel.

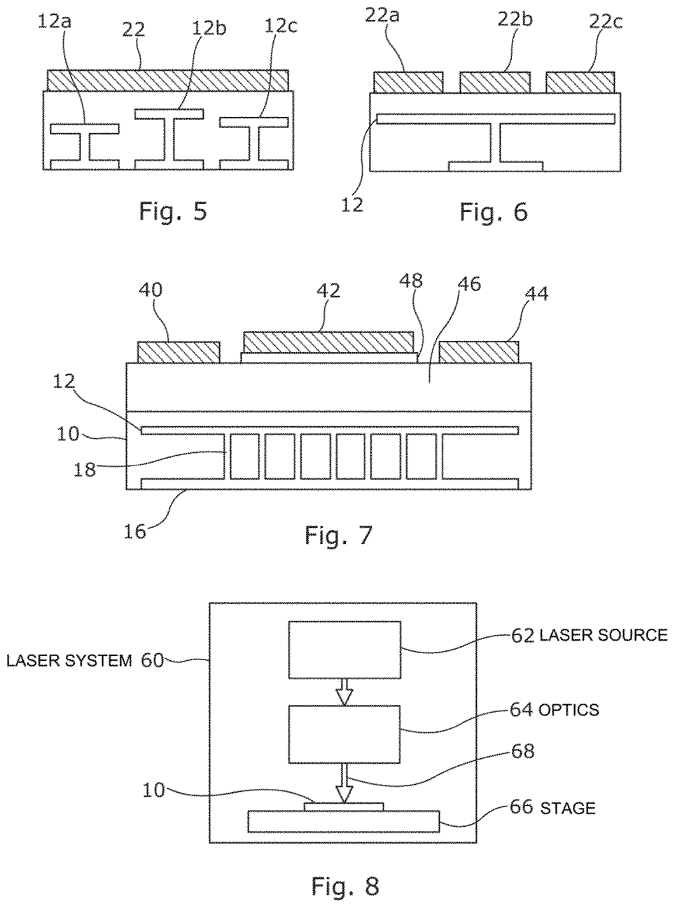

FIGS. 4, 5 and 6 show further embodiments of the invention in which multiple electronic devices are formed on the same substrate. These figures are schematic cross-sections each illustrating three devices, but not at all limited to that number. In FIG. 4, multiple devices, each essentially the same as FIG. 1, are formed side by side on a common substrate 10. Each device has its own Schottky metal contact 22a, 22b, 22c and buried electrode 12a, 12b, 12c. In the embodiment of FIG. 5, a single metal contact 22 is in common between the multiple devices. In the embodiment of FIG. 6, a single electrode 12 is in common between the multiple devices.

As illustrated in FIGS. 4 and 5, the distance from the upper metal contact 22 to the buried electrode 12 does not have to be the same for all of the devices (although it can be the same if desired). In a Schottky diode device, this distance is the channel width, which determines the power handling capability and ability to turn the device on-off.

Another embodiment of the invention is illustrated in FIG. 7 in which the upper portion shows, in cross-section, a field effect transistor (FET) comprising three terminals, source 40, gate 42, and drain 44. A semiconductor lateral channel 46 is provided between the source and drain. An insulator 48 separates the gate 42 from the channel 46. Application of a voltage to the gate 42 alters the conductivity between the source 40 and drain 44. This embodiment of the present invention provides a diamond substrate with buried electrode for providing a bias potential (voltage) to the device. This is shown in the lower portion of FIG. 7, comprising the diamond substrate 10, electrode 12, contact region 16 and conductive pillars 18.

The FET can be formed from any suitable semiconductor material known in the art, including silicon, III-V compound semiconductors, graphene and so forth. The diamond substrate 10, in one embodiment, can be grown on the back of a silicon wafer. Or in another embodiment, the FET electronic structure is grown or fabricated on top of the diamond substrate. According to another embodiment, the FET can itself be a diamond-based electronic device and can be integral or monolithic with the substrate 10.

The FET is merely one illustrative example of a semiconductor electronic structure that can be provided on the diamond substrate 10; embodiments of the invention are not limited to the FET.

In this and any other embodiments of the invention, it can be useful to have a back-gate for biasing the channel region during operation. Such a gate can also be used to electrically de-couple the active device region from the body of the substrate, reducing parasitic capacitance effects. Further, buried conductive layers, similar to the back-gate, can be extended beyond the active device dimensions to enable electric field profiles within the active device region to be engineered, similar to the way field plates do so in conventional FET structures.

In general, devices embodying the invention can be good for operation at high and low power, high and low frequency, quantum and classical regimes, with all levels of integration. Diamond-based devices provide advantages, such as low turn-on voltage, quick turn-on time, and low power loss. Devices embodying the invention are particularly suitable for high power regimes, such as operating at 500V or above, and carrying 0.5A or greater. Applications in an electricity power grid require voltages of the order of kV, and current of the order of 10 s of A. Another application is in power electronics for electric vehicles and air conditioning units, where the voltages can be of the order of 100V. Devices with linear or non-linear electronic properties embodying the invention can also be used to create neural networks for applications such as reservoir computing, neuromorphic computing, feed-forward networks, recurrent neural networks and the like.

A method of producing an electronic device embodying the invention will now be described with reference to the apparatus illustrated in FIG. 8. A diamond substrate 10 is positioned in a laser system 60. The laser system 60 comprises a laser source 62, optics 64, and a stage 66 on which the diamond substrate is positioned. An example of a suitable laser source 62 is an amplified Ti:sapphire laser emitting 100 fs pulses with a repetition rate of 1 kHz at a wavelength of 790 nm, and an energy per pulse in the region of 100 nJ. The optics 64 are used to condition and shape the laser radiation 68, and to direct the laser radiation 68 to a spot within the substrate 10.

Exposure of the substrate 10 to the laser radiation 68 results in an energy density at a focal spot that exceeds the threshold for modification to form at least some graphitic phase. The volume of this spot (or pixel, or more strictly voxel) is of the order of one or a few microns in each direction, slightly more in the direction of propagation of the laser. The substrate 10 and the laser radiation 68 are moved relative to one another. This can be achieved by moving the substrate 10 by means of the stage 66 being a translation stage while keeping the rest of the laser system 60 stationary, or by moving the laser system 60 and keeping the substrate 10 stationary, or by adjusting the optics 64 to shift the laser radiation 68 and/or the focal spot position, or by a combination of any of the above. For example the depth of formation of the modified material within the substrate can be controlled by moving the stage 66, which can be done with very fine precision (nanometers).

As the laser radiation 68 is moved relative to the substrate 10, a modified graphitic track is ‘written’ into the substrate. Such a track is also known as a graphitic micro-channel (GMC). Further details regarding writing GMCs into diamond substrates are known in the art, and can be gleaned, for example from WO 2019/030520 A1.

To write a 2D structure, such as an electrode 12 in the form of a plate, the substrate is rastered. This process can be repeated at different depths to form thicker structures such as 3D blocks 30. The relative movement of substrate 10 and laser radiation 68 can be computer-controlled to create the graphitic regions, such as electrodes 12, contact regions 16 and pillars 18, as required.

The graphitic regions can all be written from one side of the substrate. However, to form an electrode 12 at a relatively shallow depth beneath the second surface 20 of the substrate, the substrate is preferably positioned such that the laser radiation 68 enters the substrate from the second surface 20. The other graphitic regions can be written with the laser radiation entering the substrate from the first surface 14. The substrate is turned over between these writing operations (which can be performed in either order). The whole writing process can take of the order of 30 minutes.

Although described above as a spot writing process, in an alternative embodiment, a suitably energetic electromagnetic radiation source (not necessarily a laser), can be imaged to a desired pattern which is projected into the substrate at a desired focal depth. The graphitic regions are then created in a single exposure, or a small number of discrete exposures.

After creating the graphitic regions, the entire substrate 10 can be annealed, for example in an inert gas atmosphere at temperatures greater and 800 degrees C., to relieve stresses within the lattice caused by the modified carbon bonds.

More electronic devices according to further embodiments of the invention will now be described. These all comprise a non-conductive diamond substrate on or in which conductive or semi-conductive structures or regions are formed, and which also employ modified (i.e. graphitic) diamond substrate region or regions as electrodes, such as contacts or gates.

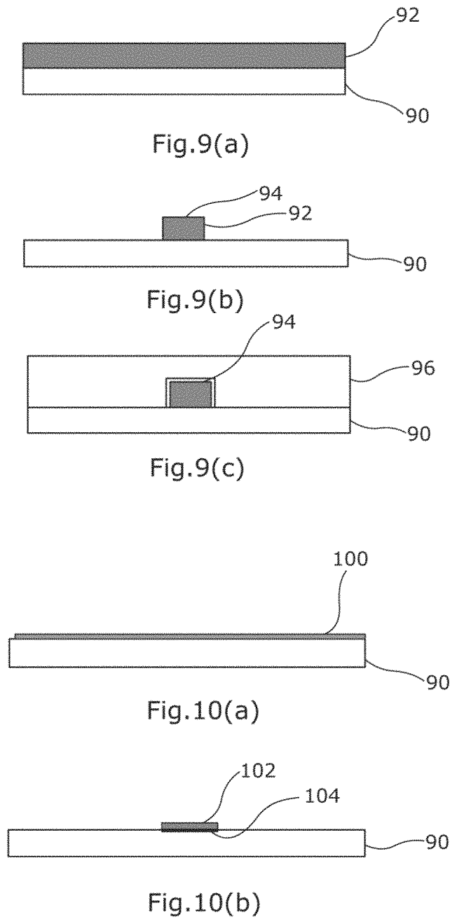

Two methods of fabricating the electronic devices will firstly be described with reference to FIGS. 9 and 10.

FIG. 9 illustrates one method of fabricating such an electronic device (shown in cross-section). A non-conductive diamond substrate 90 is provided, and a doped (n-type or p-type) epi-layer 92 is grown on one surface as shown in FIG. 9(a), using a dopant such as boron. The epi-layer can be lightly doped to form a semi-conductive device region, or can be heavily doped to form a conductive or super-conductive device region. The epi-layer 92 is formed as a mesa on the substrate 90, as illustrated in FIG. 9(b), to provide a channel 94 for conduction. The mesa can be formed either by reactive-ion etching of the epi-layer 92, or by selectively growing the epi-layer 92 only on the required region of the substrate 90. As shown in FIG. 9(c), an optional non-conductive capping layer 96 can be over-grown, if desired. Radiation induced graphitic electrodes are then formed/patterned in the substrate, for example using the method described above with reference to FIG. 8, and metal contact pads are formed as necessary.

FIG. 10 illustrates another method of fabricating such an electronic device (shown in cross-section). A non-conductive diamond substrate 90 is provided, and the surface is treated to have hydrogen surface moieties (hydrogen terminated). A protective layer 100 of a material with appropriate electronegativity (such as MoO₃ and/or other transition metal oxide, or surface adsorbate) is added to passivate and provide stability (see FIG. 10(a)). The passivation and/or surface adsorbates create charge transfer to the substrate, thereby producing a sub-surface 2D carrier gas (2DEG (2D electron gas) or 2DHG (2D hole gas)) by surface transfer doping. The regions of the surface of the substrate in which conduction is not required are defined by pinning the Fermi level with surface chemical functionalization (for example being oxygen or fluorine terminated) using lithographic techniques to define the pattern of the non-conductive regions. As shown in FIG. 10(b) this leaves surface adsorbates/passivation 102 above a 2D carrier gas comprising a conductive region or channel 104. Radiation induced graphitic electrodes are then formed/patterned in the substrate, for example using the method described above with reference to FIG. 8, and metal contact pads are formed as necessary. This enables the sub-surface conductive channel 104 to be contacted from behind, with electrically conductive, radiation graphitized, diamond wire, as well as enabling electrostatically gating/coupling the channel 104.

In the drawings illustrating the exemplary embodiments of electronic devices, the following reference signs are used:
S—source
D—drain
G—gate (G₁-Gₙ)
90—diamond substrate (non-conductive)
94, 104—channel (conductive)
102—surface adsorbates or passivation
106—metal layer (ohmic metal for gate contact; ohmic or Schottky-barrier-forming metal for source and drain)
108—graphitic (modified diamond) buried gate electrode
110—graphitic conductive pillar (access channel)
112—graphitic contact region (access contact pad)
   The relative dimensions, spacings, and aspect ratios of the features in the drawings are arbitrary, and can be varied as desired.

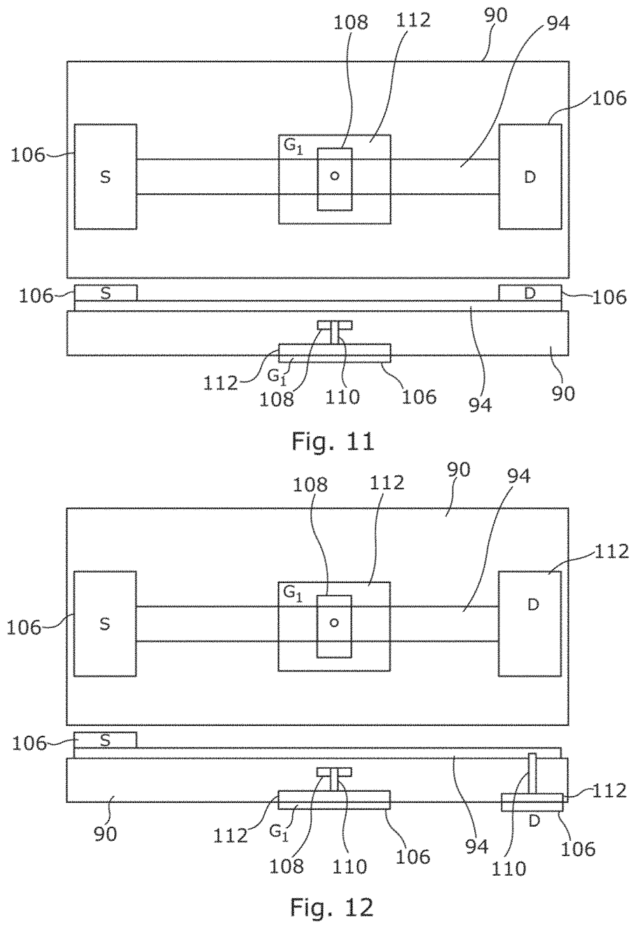

FIGS. 11 to 22 each comprise an upper and a lower portion; the upper portion shows schematically a plan (top down) view of the device (in some cases with features shown as translucent or transparent to reveal structures underneath), and the lower portion showing a cross-section through the device (typically along the center-line of the channel).

FIG. 11 shows a transistor-type electronic device, with a bottom gate (also known as a back gate or field plate). Alternatively, or in addition, a top gate (not shown) can be provided for a MESFET or MOSFET device.

FIG. 12 shows a device that is quasi-lateral because the conduction is ‘horizontal’ through the channel 94, but the device is ‘vertical’ because the source and drain are on opposite surfaces of the device; however, the lateral displacement of the source and drain provides the device with a higher break-down voltage than a simple vertical device of the same thickness.

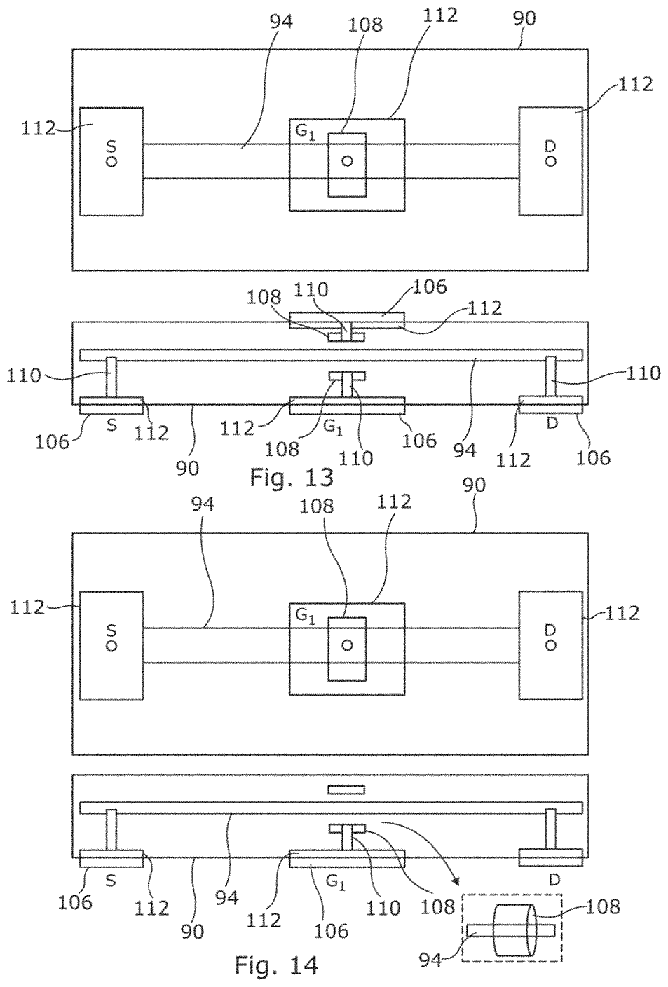

FIG. 13 shows a device in which the channel 94 is buried (over grown by non-conductive diamond capping layer). The source, drain and a gate contact are on the bottom surface of the device. A top gate can also optionally be provided, as illustrated; the gates are electrically independent of each other. Side gates are also possible in addition to, or instead of top and/or bottom gates.

The electronic device of FIG. 14 is similar to that of FIG. 13 except that the graphitic buried gate electrode 108 is formed so as to wrap around the channel 94. The gate electrode 108 can be a hollow cylinder, as illustrated in the inset of FIG. 13, or an open-ended box, or some other generally tubular form.

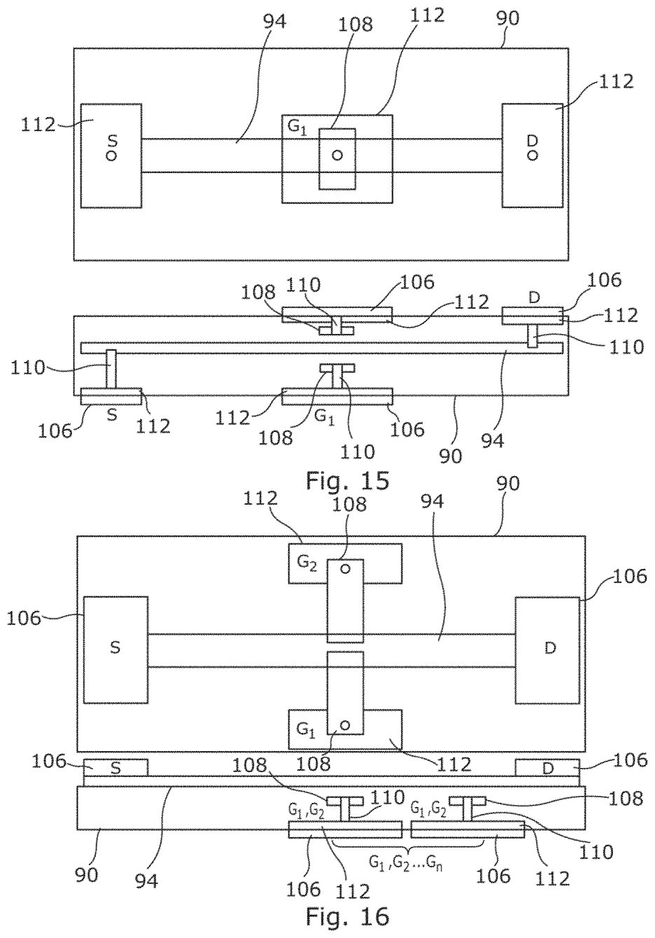

FIG. 15 shows a quasi-lateral device, similar to FIG. 12, but with a buried channel 94 (like FIGS. 13 & 14). The device can have individual top and/or bottom and/or side gates, like the embodiment of FIG. 13; or the device can have a wrap-around gate like the embodiment of FIG. 14.

FIG. 16, plan view, shows a device with a split gate (a pair of gate electrodes with a small separation). FIG. 16, cross-section view, shows that multiple split gates can be provided along the length of the channel. If the channel 94 is semi-conductive, each split gate of this device can be used to implement a single electron transistor (SET) or quantum point contact. If the channel 94 is heavily doped and superconductive, each split gate of this device can be used to implement a quantum point contact or Josephson junction—provided the constriction (width of the gate along the length of the channel) is short compared to the superconducting coherence length.

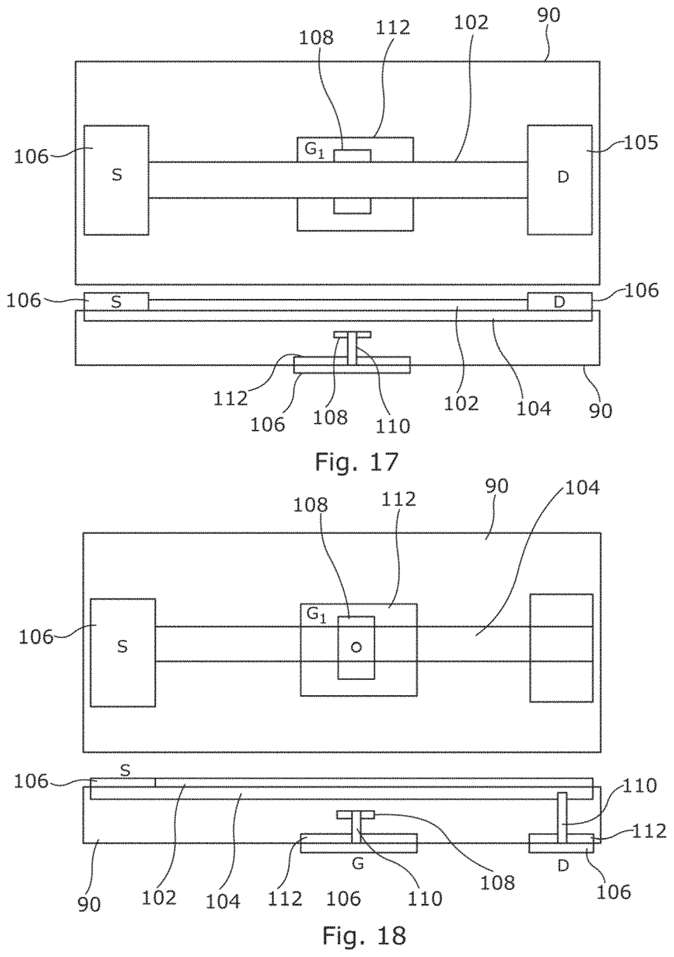

FIG. 17 shows a device fabricated by the technique of FIG. 10, in which the channel 104 is defined by surface functionalization and charge transfer. This structure avoids the need for damaging surface passivation with a top gate and/or oxide, as with conventional devices.

FIG. 18 shows a device that is quasi-lateral because the conduction is ‘horizontal’ through the channel 104, but the device is ‘vertical’ because the source and drain are on opposite surfaces of the device; however, the lateral displacement of the source and drain provides the device with a higher break-down voltage than a simple vertical device of the same thickness.

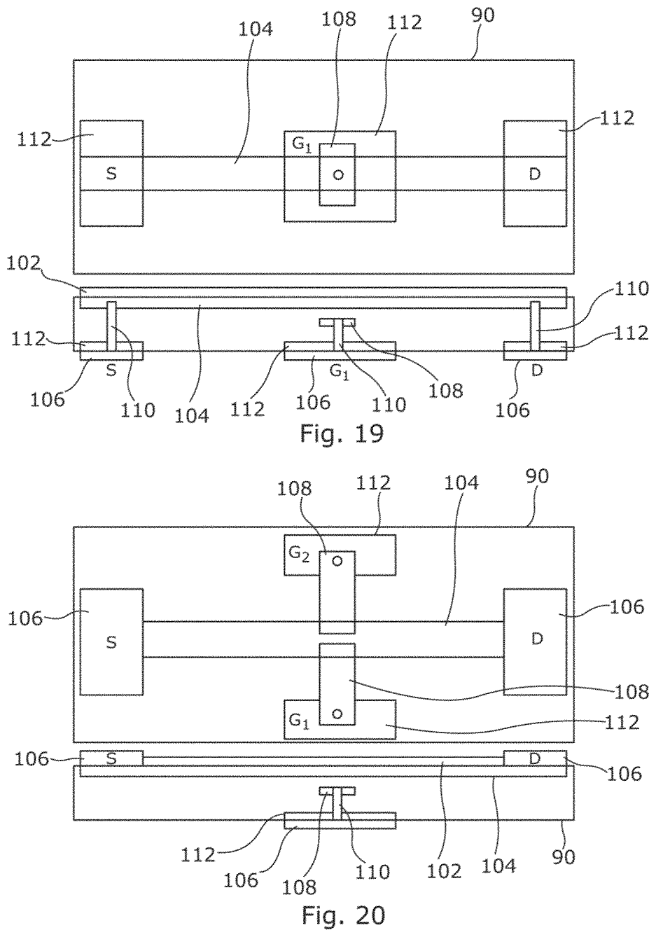

FIG. 19 illustrates a device fabricated by the technique of FIG. 10, in which the gate, source, and drain are all provided on the bottom surface. The avoids the need for any damaging top surface passivation with gate and/or oxide, or indeed any processing of the top surface after creation of the surface charge transfer layer (channel 104).

FIG. 20 shows a split-gate surface induced channel SET device. The source S and drain D can be provided on the top (as shown in FIG. 20), or on the bottom (like FIG. 19), or one on each (like FIG. 18).

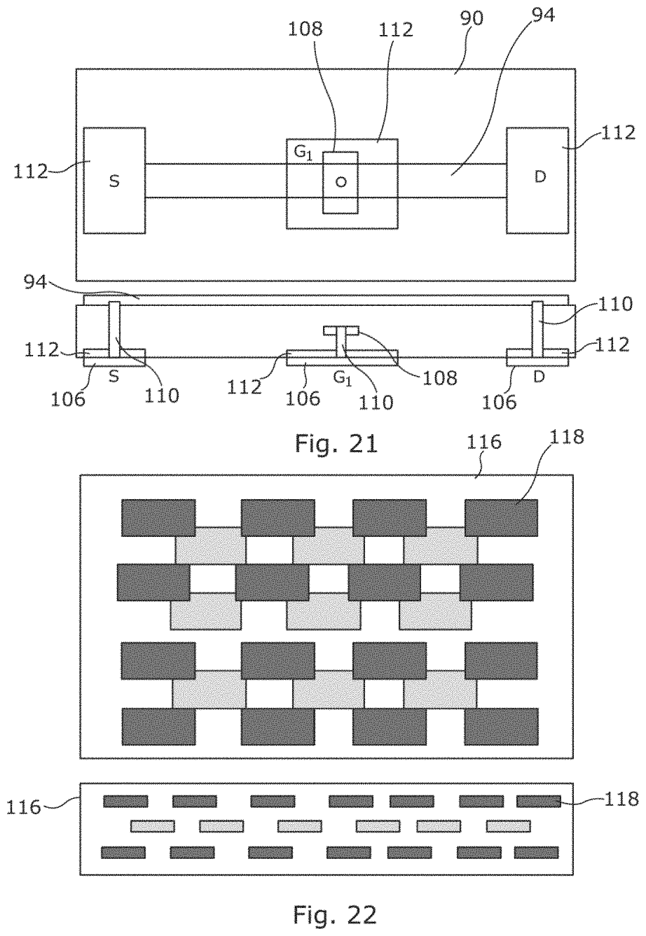

FIG. 21 shows a device in which a non-diamond semiconductor channel 94 is grown or transferred onto a diamond substrate 90 (non-conductive diamond wafer). The G, S, and D contacts can all be on the bottom of the diamond substrate 90, as shown, or some or all of the contacts can be on the top of the diamond substrate 90. The surface semiconductor does not have to be just a simple channel, but can comprise electronically active components or devices. The diamond substrate 90 can act as a heat sink and as a dielectric between the back gate and the semiconductor devices.

The laser-writing process, described with reference to FIG. 8, can enable a high level of integration of electronic devices on a single substrate because the devices can be arranged in 3D within the diamond. FIG. 22 shows a diamond chip 116 in which each block 118 schematically represents some sort of electronic device (not necessarily all the same). Connections between devices and to the top, bottom and/or sides of the chip can be provided by laser-written wires. The devices can be spatially off-set from each other and arrayed vertically and horizontally. Very high levels of integration are possible. So, this aspect of the invention provides a diamond substrate within which are provided a plurality of electronic devices connected by conductive paths comprising modified substrate (e.g. graphitic wires).

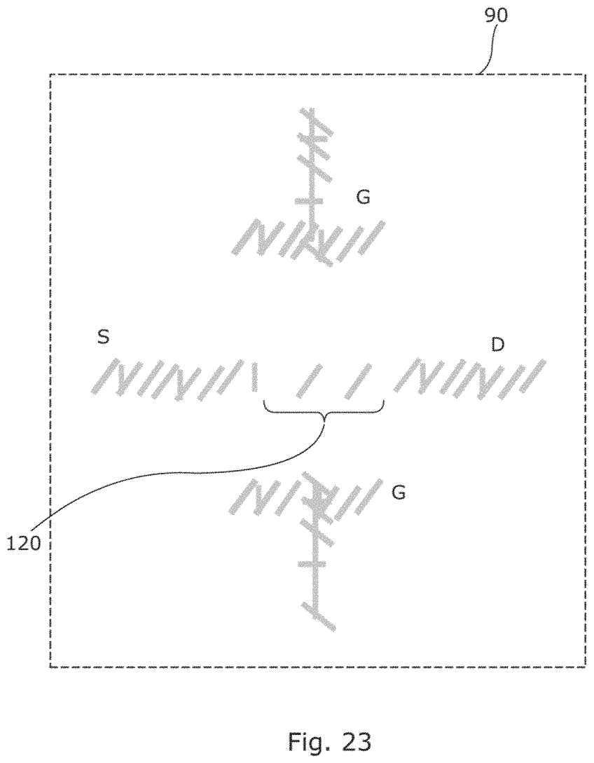

An electronic device according to a further embodiment of the invention is illustrated schematically in FIG. 23 on a portion of a diamond substrate 90, greatly magnified. Graphitic wires can behave as a semiconductor, particularly if the percolation network of graphitic platelets is not very dense. The density of graphitic platelets is illustrated schematically by the density of grey rectangles in FIG. 23. The gate G (or gates), source S, and drain D, are laser-written to be good conductors; a channel 120 is laser-written to have a sparser network of graphitic platelets (so would be more resistive). The bulk diamond acts as the dielectric. An electric field applied by the gate G (or gates) modulates the semiconducting diamond between the graphitic platelets of the channel 120 to enable the conductivity of the channel to be controlled. Devices embodying this aspect of the invention can have gate geometries and wiring according to any of the preceding embodiments; the difference is that the channel itself comprises diamond that has been ‘machined’ (e.g. laser-written) to have a desired density of ‘graphitic’ or modified diamond content, such as graphitic platelets, so as to be semi-conductive. Devices according to this embodiment of the invention can be entirely laser-written, which provides a very cheap and quick process. Multiple devices can be written simultaneously, for example by using adaptive optics to expose numerous structures in parallel, so the fabrication of the devices is highly scalable. So, in its broadest sense, this aspect of the invention provides an electronic device comprising a diamond substrate in which electrically conductive and/or semiconductive features are defined by regions of differing density of modification of the diamond, such as differing density of graphitization. There is also provided a method of producing such a device by radiation-induced modification of the diamond substrate, wherein the modification is modulated to produce regions of differing density of modification. In a preferred example, the radiation is laser radiation, and the features are laser-written. In another preferred example, the modification is modulated by varying the intensity of the radiation and/or the exposure time of different regions of the substrate to the radiation.

The dimensions of any of the devices and device features described herein can be selected to suit the particular application, whether it be for signal processing or for high-power electronic control, etc., so all of the feature dimensions can be in the range of from approximately 1 nm up to several mm.

In accordance with the provisions of the patent statutes, the present invention has been described in what is considered to represent its preferred embodiment. However, it should be noted that the invention can be practiced otherwise than as specifically illustrated and described without departing from its spirit or scope.

1-16. (canceled)

17. An electronic device comprising:
a diamond substrate;
an electrode provided within the substrate; and
wherein the electrode is a modified area of the substrate, the modified area being a 2D region or a 3D region.

18. The device according to claim 17 wherein the electrode is formed as a plate or a block.

19. The device according to claim 17 wherein the electrode is connected to a surface of the substrate by at least one conductive pillar.

20. The device according to claim 17 wherein an electrical contact to the electrode is provided at a first surface of the substrate, the contact being a region of modified substrate surface.

21. The device according to claim 17 wherein the electrode is spaced apart from a second surface of the substrate by a predetermined distance.

22. The device according to claim 21 wherein the distance is in a range of from 5 μm to 20 μm.

23. The device according to claim 21 including a metal contact on the second surface of the substrate, and a conductive path or a semi-conductive path formed through the substrate between the electrode and the metal contact.

24. The device according to claim 23 adapted to operate as a Schottky diode.

25. The device according to claim 17 including a semiconductor electronic structure on the substrate, and wherein the electrode is adapted to provide a bias potential to the semiconductor electronic structure.

26. The device according to claim 25 wherein the semiconductor electronic structure is a field-effect transistor.

27. The device according to claim 17 wherein the substrate is a natural diamond or a synthetic diamond and is single crystal or poly-crystalline.

28. The device according to claim 17 wherein the modified area of the substrate comprises at least one of a graphitic carbon, amorphous carbon, and a combination of sp2 and sp3 phases of carbon.

29. The device according to claim 17 including at least two of the electrode formed within the substrate.

30. A method of producing an electronic device, the method comprising the steps of:
positioning a diamond substrate in a laser system; and
exposing the substrate to laser radiation generated by the laser system to modify an area of the substrate thereby creating an electrode being a 2D electrode or a 3D electrode within the substrate.

31. The method according to claim 30 including moving at least one of the substrate and the laser radiation relative to one another to write the modified area within the substrate and create the electrode.

32. The method according to claim 30 including exposing the substrate to the laser radiation to form a contact region at a first surface of the substrate.

33. The method according to claim 30 including exposing the substrate to the laser radiation to form at least one conductive pillar connecting the electrode to a first surface of the substrate.

34. The method according to claim 33 including proving a conductive contact on a second surface of the substrate.
